(19) United States
(12) Patent Application Publication
(10) Pub. No.: US 2026/0032831 A1
(43) Pub. Date: Jan. 29, 2026

(54) ELECTRONIC DEVICE

(71) Applicant: LITE-ON TECHNOLOGY CORPORATION, Taipei (TW)

(72) Inventors: Che-Han Lin, Taipei (TW); Chung-Ting Cheng, Taipei (TW); Tsung-Po Hsu, Taipei (TW)

(21) Appl. No.: 19/190,843

(22) Filed: Apr. 28, 2025

(30) Foreign Application Priority Data
Jul. 29, 2024 (CN) 202421804393.7

(51) Int. Cl. H05K 5/00; H05K 5/02

(52) U.S. Cl. CPC H05K 5/0069; H05K 5/0247

(57) ABSTRACT

An electronic device includes a housing and a connector. The housing includes a housing abutting portion located inside the housing. The connector includes a connector abutting portion. The housing abutting portion and the connector abutting portion abut against each other.

This application claims the benefit of People's Republic of China application Serial No. 202421804393.7, filed on Jul. 29, 2024, the subject matter of which is incorporated herein by reference.

### BACKGROUND OF THE INVENTION

### Field of the Invention

The invention relates in general to an electronic device.

### Description of the Related Art

A conventional electronic device generally includes a connector for electrically connecting to an external device. The connector is generally assembled into a housing of the electronic device. If the connection between the connector and the housing is not good, the connector may be loose relative to the housing or even fall off.

### SUMMARY OF THE INVENTION

According to an embodiment of the present invention, an electronic device is provided. The electronic device includes a first housing and a connector. The first housing includes a first housing abutting portion located inside the first housing. The connector includes a first connector abutting portion. The first housing abutting portion and the first connector abutting portion abut against each other.

According to another embodiment of the present invention, an electronic device is provided. The electronic device includes a first housing and a connector. The first housing includes a first housing abutting portion and a second housing abutting portion. The connector includes a first connector abutting portion and a second connector abutting surface. The first housing abutting portion contacts the first connector abutting portion on a first side of the first housing, and the second connector abutting surface contacts the second housing abutting portion on a second side of the first housing.

According to another embodiment of the present invention, an electronic device is provided. The electronic device includes a first housing and a connector. The first housing includes a first abutting portion located outside the first housing. The connector includes a first body abutting surface. The first abutting portion and the first body abutting surface abut against each other.

According to another embodiment of the present invention, an electronic device is provided. The electronic device includes a first housing and a connector. The first housing includes a first abutting portion extending outward from the first housing at a position corresponding to an opening. The connector is disposed in the opening of the first housing, wherein the connector comprises a first body abutting surface in contact with the first abutting portion.

According to another embodiment of the present invention, an electronic device is provided. The electronic device includes a housing and a connector. The housing includes a first housing abutting surface and a second housing abutting surface. The connector includes a first connector abutting surface and a second connector abutting surface. The first housing abutting surface is in contact with the first connector abutting surface along a first axis, the second housing abutting surface is in contact with the second connector abutting surface along a second axis, and the second axis is not parallel to the first axis.

According to another embodiment of the present invention, an electronic device is provided. The electronic device includes a housing and a connector. The housing includes a first housing abutting surface and a second housing abutting surface. The connector includes a first connector abutting surface and a second connector abutting surface. The first housing abutting surface is in contact with the first connector abutting surface along a first axis, the second housing abutting surface is in contact with the second connector abutting surface along a second axis not parallel to the first axis.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A and 1B illustrate schematic diagrams of an electronic device 100 according to an embodiment of the present invention from different viewing angles;

FIG. 2A illustrates a schematic diagram of a cross-sectional view of the electronic device 100 in FIG. 1A in a direction 2A-2A′;

FIG. 2B illustrates a schematic diagram of a cross-sectional view of the electronic device 100 in FIG. 1A in a direction 2B-2B′;

FIG. 3A illustrates a schematic diagram of an exploded view of the electronic device 100 in FIG. 1A;

FIG. 3B illustrates a schematic diagram of an exploded view of the electronic device 100 in FIG. 1B;

FIG. 4 illustrates a schematic diagram of a top view of the electronic device 100 in FIG. 1A;

FIG. 5 illustrates a schematic diagram of an electronic device 200 according to another embodiment of the present invention;

FIG. 6 illustrates a schematic diagram of an electronic device 300 according to another embodiment of the present invention; and

FIG. 7 illustrates a schematic diagram of an exploded view of the electronic device 300 in FIG. 6.

### DETAILED DESCRIPTION OF THE INVENTION

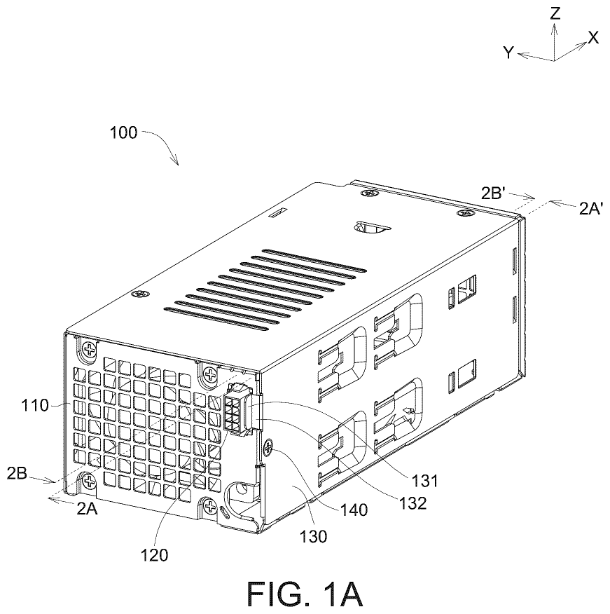

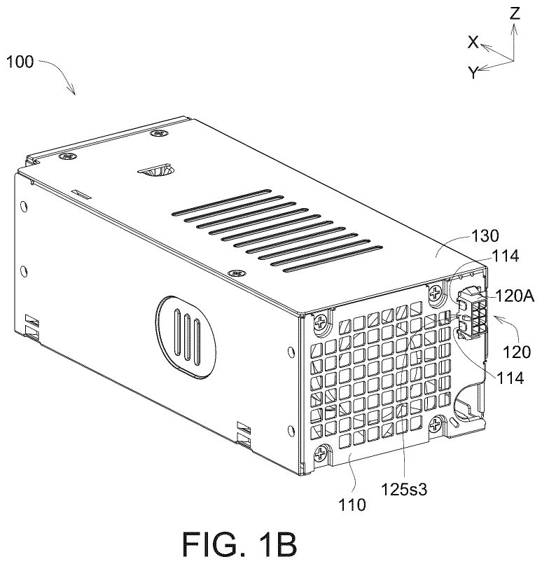

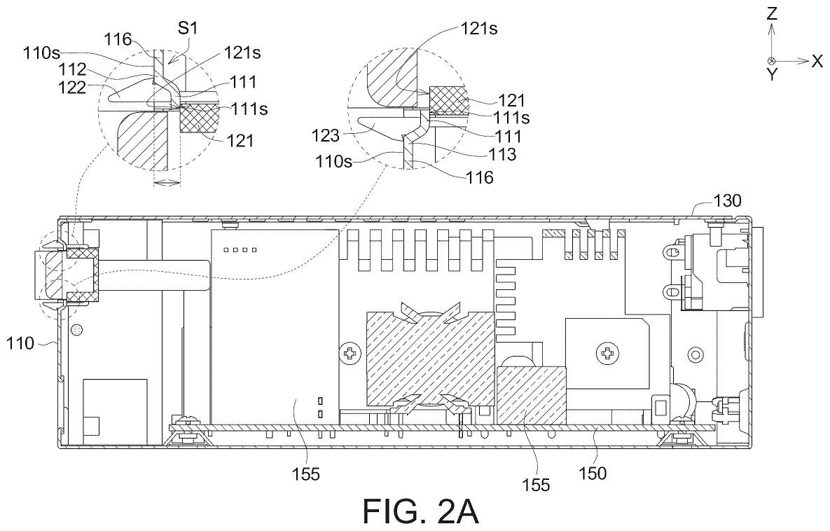

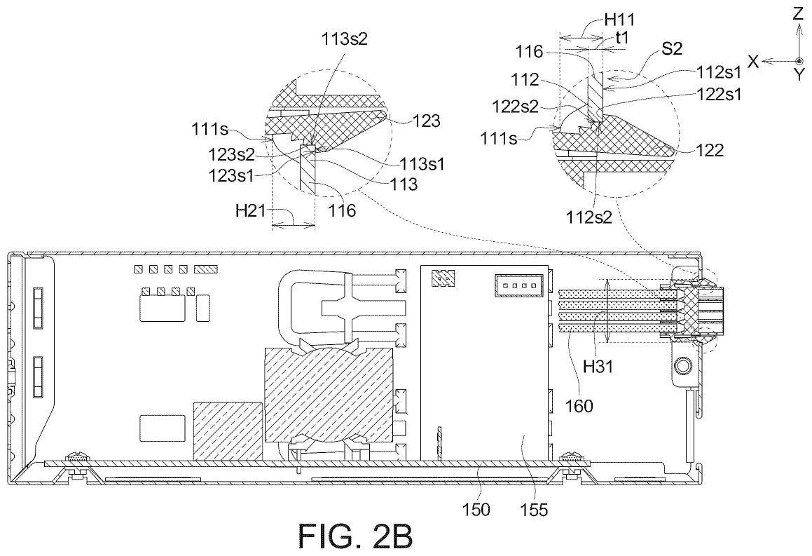

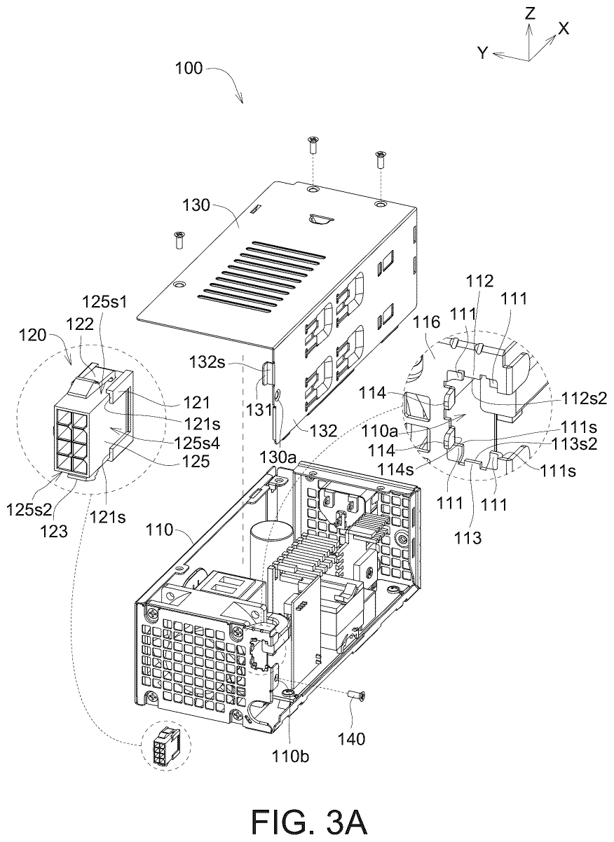

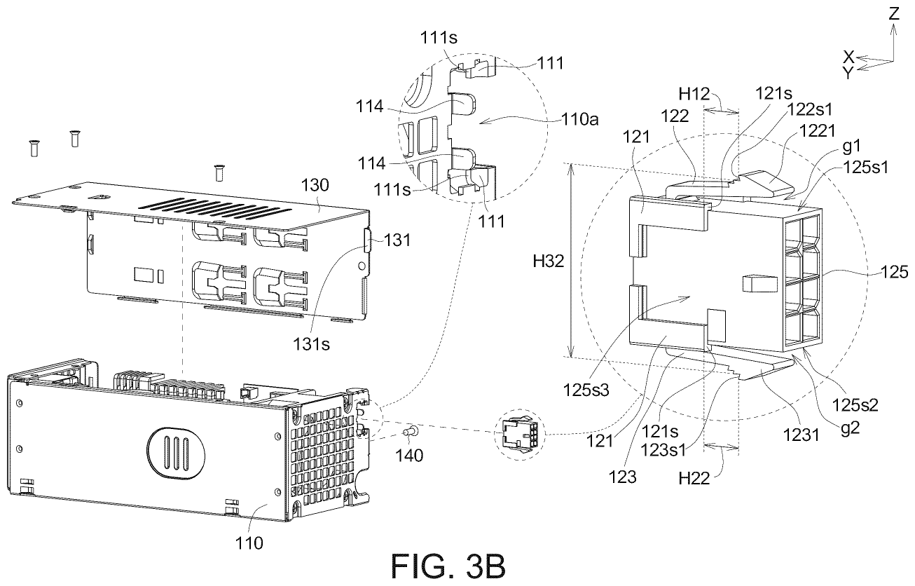

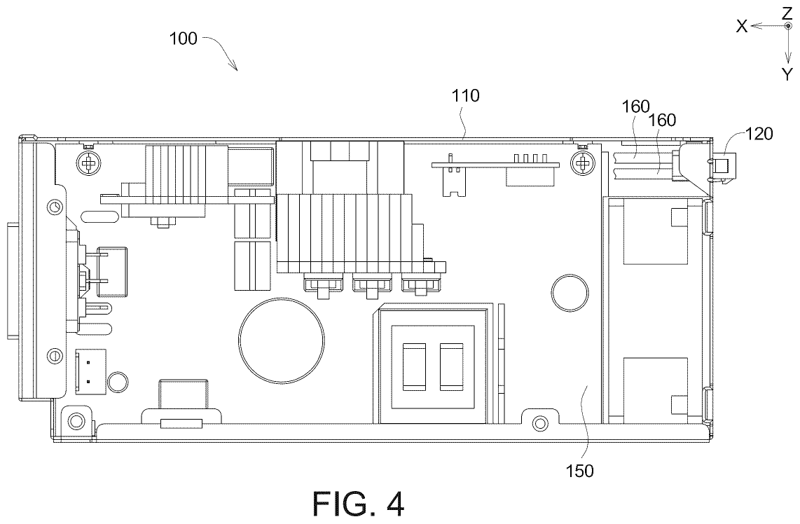

Referring to FIGS. 1A to 4, FIGS. 1A and 1B illustrate schematic diagrams of an electronic device 100 according to an embodiment of the present invention from different viewing angles, FIG. 2A illustrates a schematic diagram of a cross-sectional view of the electronic device 100 in FIG. 1A in a direction 2A-2A′, FIG. 2B illustrates a schematic diagram of a cross-sectional view of the electronic device 100 in FIG. 1A in a direction 2B-2B′, FIG. 3A illustrates a schematic diagram of an exploded view of the electronic device 100 in FIG. 1A, FIG. 3B illustrates a schematic diagram of an exploded view of the electronic device 100 in FIG. 1B, and FIG. 4 illustrates a schematic diagram of a top view of the electronic device 100 in FIG. 1A. The electronic device 100 is, for example, a power supply or other electronic device with a connector.

As illustrated in FIGS. 1A and 2A, the electronic device 100 includes a first housing 110, a connector 120, a second housing 130, a fixing element 140 and a circuit board 150. The first housing 110 includes at least one first housing abutting portion 111, and the first housing abutting portion 111 is located inside the first housing 110. The connector 120 includes at least one first connector abutting portion 121. The first housing abutting portion 111 and the first connector abutting portion 121 abut against each other. As a result, the first housing abutting portion 111 may block the connector 120 from being separated from the first housing 110 in a −X direction, thereby increasing the fixation between the connector 120 and the housing.

As illustrated in FIG. 2A, the first housing 110 includes a housing body 116 having an outer surface 110s. The components and/or structures that extend toward an inside side of the outer surface 110s or do not protrude relative to the outer surface 110s are all so-called “located inside the first housing 110” herein. In an embodiment, the housing body 116 and the first housing abutting portion 111 are connected to each other, and form, for example, an integrally formed structure. In terms of manufacturing process, the first housing 110 including the housing body 116 and the first housing abutting portion 111 may be formed by, for example, a stamping technique and/or a bending technique. In terms of material, the first housing 110 may be formed of a metal, for example.

As illustrated in FIGS. 2A and 3A, the first housing abutting portion 111 protrudes toward the inside of the first housing 110 relative to the outer surface 110s and has a first housing abutting surface 111s. The first housing abutting surface 111s faces the inside of the first housing 110. The connector 120 includes a body 125. The body 125 has a first lateral surface 125s1. The first connector abutting portion 121 protrudes relative to the first lateral surface 125s1 and has a first connector abutting surface 121s. The first housing abutting surface 111s abuts against the first connector abutting surface 121s.

As illustrated in FIGS. 2A and 3A, the first housing abutting portion 111 extends in +X direction relative to the outer surface 110s to abut against the first connector abutting surface 121s of the connector 120. In addition, depending on a geometric shape of the first housing abutting surface 111s and a geometric shape of the first connector abutting surface 121s, the first housing abutting surface 111s and the first connector abutting surface 121s may be a point contact form, a line contact form or a surface contact form.

As illustrated in FIGS. 2A and 2B, the first housing abutting portion 111 contacts the first connector abutting portion 121 on a first side S1 of the first housing 110, and the second connector abutting surface 122s1 contacts the second housing abutting portion 112 on a second side S2 of the first housing 110, wherein the first side S1 is opposite to the second side S2.

As illustrated in FIGS. 2B and 3A, the first housing 110 further has a second housing abutting surface 112s1. The second housing abutting surface 112s1 is, for example, a portion of the outer surface 110s of the first housing 110. The connector 120 further includes at least one first elastic portion (or elastic arm) 122. The first elastic portion 122 is connected to the first lateral surface 125s1 and has a second connector abutting surface 122s1. The second connector abutting surface 122s1 and the second housing abutting surface 112s1 abut against each other. As a result, the second housing abutting surface 112s1 may block the connector 120 from being separated from the first housing 110 in −X direction, thereby increasing the fixation between the connector 120 and the housing.

As illustrated in FIGS. 2B and 3A, the first housing 110 further includes a second housing abutting portion 112, and the second housing abutting portion 112 has the aforementioned second housing abutting surface 112s1. The second housing abutting portion 112 is connected to the housing body 116 and extends in the direction toward the first lateral surface 125s1. In the present embodiment, the second housing abutting portion 112 extends from the housing body 116 along −Z direction, so that the second housing abutting surface 112s1 of the second housing abutting portion 112 and the second connector abutting surface 122s1 of the connector 120 may face each other along X-axis (e.g., a first axis). As a result, when the connector 120 is assembled with the first housing 110, the second connector abutting surface 122s1 and the second housing abutting surface 112s1 may abut against each other.

In an embodiment, the housing body 116 and the second housing abutting portion 112 are connected to each other, and the housing body 116 and the second housing abutting portion 112 are integrated into a one-piece structure. In terms of manufacturing process, the first housing 110 including the housing body 116 and the second housing abutting portion 112 may be formed by, for example, a stamping technique and/or a bending technique.

As illustrated in FIGS. 2B and 3B, there is a first distance H11 between the second housing abutting surface 112s1 of the second housing abutting portion 112 and the first housing abutting surface 111s of the first housing abutting portion 111 along X-axis, and there is a second distance H12 between the second connector abutting surface 122s1 of the first elastic portion 122 and the first connector abutting surface 121s of the first connector abutting portion 121. In an embodiment, the second distance H12 is substantially equal to or less than the first distance H11. As a result, when the connector 120 is assembled with the first housing 110, the second housing abutting surface 112s1 of the second housing abutting portion 112 and the second connector abutting surface 122s1 of the first elastic portion 122 may abut against each other, and the first housing abutting surface 111s of the first housing abutting portion 111 and the first connector abutting surface 121s of the first connector abutting portion 121 may abut against each other. In addition, the second distance H12 between the first connector abutting portion 121 and the second connector abutting surface 122s1 is greater than a thickness t1 of the first housing 110.

In summary, due to the first housing abutting surface 111s of the first housing abutting portion 111 and the first connector abutting surface 121s of the first connector abutting portion 121 abutting against each other, and the second connector abutting surface 122s1 and the second housing abutting surface 112s1 abutting against each other, it may constrain a displacement DoF of the first housing 110 and the connector 120 along X-axis, and the first housing 110 and the connector 120 will not easily cause unstable relative shaking due to external force, and the connection stability will not be negatively affected.

As illustrated in FIGS. 2B and 3A, the second housing abutting portion 112 of the first housing 110 further has a third housing abutting surface 112s2. The third housing abutting surface 112s2 is adjacent to the second housing abutting surface 112s1. For example, the first housing 110 has an opening 110a, which extends from the second housing abutting surface 112s1 toward the inside of the first housing 110. In an embodiment, the opening 110a is, for example, a through hole. The third housing abutting surface 112s2 is a lateral wall of the opening 110a and is connected to the second housing abutting surface 112s1. Furthermore, the second housing abutting surface 112s1 and the third housing abutting surface 112s2 are substantially perpendicular to each other.

As illustrated in FIG. 2B, the second connector abutting surface 122s1 intersects with the third connector abutting surface 122s2, wherein an included angle between the second connector abutting surface 122s1 and the third connector abutting surface 122s2 is, for example, a right angle, but it may also be an acute angle or an obtuse angle. In an embodiment, the first elastic portion 122 has a stepped structure, and the second connector abutting surface 122s1 and the third connector abutting surface 122s2 are two surfaces of the stepped structure.

As illustrated in FIGS. 3A and 3B, the structure of the first elastic portion 122 is in a free state. As illustrated in FIG. 2B, after the connector 120 is assembled with the first housing 110, the first elastic portion 122 is deformed. The deformed first elastic portion 122 provides an elastic restoring force on the third housing abutting surface 112s2 of the second housing abutting portion 112 to abut against the third housing abutting surface 112s2 of the second housing abutting portion 112. Such elastic restoring force may also increase a resistance of the connector 120 and the first housing 110 separated from each other, and it may increase the fixation between the connector 120 and the housing.

As illustrated in FIGS. 2B and 3A, the first housing 110 has a fourth housing abutting surface 113s2 and a second housing abutting surface 113s1, wherein the fourth housing abutting surface 113s2 is connected adjacent to the second housing abutting surface 113s1. For example, the opening 110a of the first housing 110 extends to the inside of the first housing 110 from the second housing abutting surface 113s1. The fourth housing abutting surface 113s2 is a lateral wall of the opening 110a and is connected to the second housing abutting surface 113s1. In addition, the fourth housing abutting surface 113s2 and the aforementioned third housing abutting surface 112s2 face two opposite directions respectively. For example, the direction (or a normal direction) of the fourth housing abutting surface 113s2 is substantially parallel to +Z direction, and the direction (or a normal direction) of the third housing abutting surface 112s2 is substantially parallel to −Z direction. In addition, the body 125 of the connector 120 further has a second lateral surface 125s2 opposite to the first lateral surface 125s1. The connector 120 further includes a second elastic portion 123. The second elastic portion 123 is connected to the second lateral surface 125s2 and has a second connector abutting surface 123s1 and a fourth connector abutting surface 123s2. The second connector abutting surface 123s1 and the fourth connector abutting surface 123s2 of the second elastic portion 123 intersect, wherein an angle between the second connector abutting surface 123s1 and the fourth connector abutting surface 123s2 is, for example, a right angle, but it may also be an acute or obtuse angle. In an embodiment, the second elastic portion 123 has a stepped structure, wherein the second connector abutting surface 123s1 and the fourth connector abutting surface 123s2 of the second elastic portion 123 are two surfaces of the stepped structure.

As illustrated in FIG. 3B, the first elastic portion 122 and the second elastic portion 123 are respectively disposed on opposite sides of the body 125. The first elastic portion 122 has a first free end 1221, and there is a gap g1 between the first free end 1221 and the body 125, that is, the first free end 1221 is movable relative to the body 125. The second elastic portion 123 has a second free end 1231, and there is a gap g2 between the second free end 1231 and the body 125, that is, the second free end 1231 is movable relative to the body 125.

As illustrated in FIGS. 2B and 3A, the second connector abutting surface 123s1 abuts against the second housing abutting surface 113s1, and the fourth connector abutting surface 123s2 abuts against the fourth housing abutting surface 113s2. For example, the fourth housing abutment surface 113s2 abuts against the fourth connector abutment surface 123s2 along Z-axis (e.g., the second axis). The first housing 110 further includes a third housing abutting portion 113, wherein the third housing abutting portion 113 is connected to the housing body 116 and extends toward the second lateral surface 125s2. The third housing abutting portion 113 has the aforementioned second housing abutting surface 113s1 and fourth housing abutting surface 113s2. In the present embodiment, the third housing abutting portion 113 extends from the housing body 116 along +Z direction, so that the second housing abutting surface 113s1 of the third housing abutting portion 113 faces the second connector abutting surface 123s1 of the second elastic portion 123 of the connector 120 along X-axis (the first axis). As a result, when the connector 120 is assembled with the first housing 110, the second connector abutting surface 123s1 of the second elastic portion 123 may abut against the fourth housing abutting surface 113s2.

As illustrated in FIGS. 2B and 3B, there is a third distance H21 between the housing abutting surface 113s1 of the third housing abutting portion 113 and the first housing abutting surface 111s of the first housing abutting portion 111 along X-axis, and there is a fourth distance H22 between the second connector abutting surface 123s1 of the second elastic portion 123 and the first connector abutting surface 121s of the first connector abutting portion 121 along X-axis. In an embodiment, the fourth distance H22 is substantially equal to or less than the third distance H21. As a result, when the connector 120 is assembled with the first housing 110, the second housing abutting surface 113s1 of the third housing abutting portion 113 may abut against the second connector abutting surface 123s1 of the second elastic portion 123, and the first housing abutting surface 111s of the first housing abutting portion 111 may abut against the first connector abutting surface 121s of the first connector abutting portion 121.

In an embodiment, the housing body 116 and the third housing abutting portion 113 are connected to each other to form, for example, a one-piece structure. In terms of manufacturing process, the first housing 110 including the housing body 116 and the third housing abutting portion 113 may be formed by, for example, a stamping technique and/or a bending technique.

As illustrated in FIGS. 3A and 3B, the second elastic portion 123 is in a free state. As illustrated in FIG. 2B, after the connector 120 is assembled with the first housing 110, the second elastic portion 123 is deformed. The deformed second elastic portion 123 provides the third housing abutting portion 113 with an elastic restoring force to abut against the third housing abutting portion 113. Such elastic restoring force may also increase the resistance of the connector 120 and the first housing 110 separated from each other, and it may increase the fixation between the connector 120 and the housing.

As illustrated in FIG. 2B, there is a fifth distance H31 between the third housing abutting surface 112s2 of the second housing abutting portion 112 and the fourth housing abutting surface 113s2 of the third housing abutting portion 113 along Z-axis. As illustrated in FIG. 3B, there is a sixth distance H32 (in a free state) between the third connector abutting surface 122s2 of the first elastic portion 122 (the third connector abutting surface 122s2 is illustrated in FIG. 2B) abuts against the fourth connector abutting surface 123s2 of the second elastic portion 123 (the fourth connector abutting surface 123s2 is illustrated in FIG. 2B) along Z-axis. In an embodiment, the fifth distance H31 is less than the sixth distance H32. As a result, when the connector 120 is assembled with the first housing 110, the third connector abutting surface 122s2 of the first elastic portion 122 and the fourth connector abutting surface 123s2 of the second elastic portion 123 may respectively abut against the third housing abutting surface 112s2 of the second housing abutting portion 112 and the fourth housing abutting surface 113s2 of the third housing abutting portion 113, and respectively apply the elastic restoring forces to the third housing abutting surface 112s2 and the fourth housing abutting surface. Face 113s2.

In summary, due to the third housing abutting surface 112s2 and the first elastic portion 122 abutting against each other and the fourth housing abutting surface 113s2 and the second elastic portion 123 abutting against each other, the displacement degrees of freedom (DoF) between the first housing 110 and the connection along Z-axis may be restrained, and it may constrain a displacement DoF of the first housing 110 and the connector 120 along Z-axis, and the first housing 110 and the connector 120 will not easily cause unstable relative shaking due to external force, and the connection stability will not be negatively affected.

In addition, in an embodiment, at least one of the first connector abutting portion 121, the first elastic portion 122 and the second elastic portion 123 and the body 125 are integrated into a one-piece structure. In terms of manufacturing process, such one-piece structure may be formed by, for example, an injection molding technology. In terms of material, the connector 120 may be formed of plastic, for example.

As illustrated in FIGS. 1B and 3B, the first housing 110 further includes at least one first abutting portion 114 located outside the first housing 110. In this description, components or structures located outside the outer surface 110s or protruding relative to the outer surface 110s are all so-called “located outside the first housing 110” in this description. The body 125 has a first body abutting surface 125s3, the first body abutting surface 125s3 is connected adjacent to the first lateral surface 125s1 and the second lateral surface 125s2. The first body abutting surface 125s3 abuts against the first abutting portion 114. The first abutting portion 114 extends from the housing body 116 along −X direction, so that the first abutting surface 114s of the first abutting portion 114 may face the first body abutting surface 125s3 of the body 125 of the connector 120. As a result, when the first housing 110 and the connector 120 are assembled, the first abutting surface 114s of the first abutting portion 114 may block the connector 120 from being separated from the first housing 110 along +Y direction.

As illustrated in FIG. 1B, the connector 120 includes a portion 120A protruding outward from the first housing 110 corresponding to an extension direction (for example, X-axis) of the first abutting portion 114.

In an embodiment, the housing body 116 and the first abutting portion 114 are connected to each other to form, for example, a one-piece structure. In terms of manufacturing process, the first housing 110 including the housing body 116 and the first abutting portion 114 may be formed by, for example, a stamping technique and/or a bending technique.

As illustrated in FIGS. 1A and 3A, the second housing 130 includes at least one second abutting portion 131 and a housing body 132. The second abutting portion 131 is connected to the housing body 132 and is located outside the second housing 130. For example, the housing body 132 has an outer surface 132s and protrudes relative to the outer surface 132s. In this description, components or structures located outside the outer surface 132s or protruding relative to the outer surface 132s are all so-called “located outside the second housing 130” in this description. In addition, the body 125 has a second body abutting surface 125s4 opposite to the first body abutting surface 125s3, wherein the second body abutting surface 125s4 is connected adjacent to the first lateral surface 125s1 and the second lateral surface 125s2. The second body abutting surface 125s4 abuts against the second abutting portion 131. The second abutting portion 131 extends from the housing body 132 along −X direction, so that the second abutting surface 131s of the second abutting portion 131 (the second abutting surface 131s is illustrated in FIG. 3B) may face the second body abutting surface 125s4 of the body 125 of the connector 120. As a result, when the second housing 130 is assembled with the connector 120, the second abutting surface 131s of the second abutting portion 131 may block the connector 120 from being separated from the second housing 130 in −Y direction.

In an embodiment, the housing body 132 and the second abutting portion 131 are connected to each other, and the housing body 132 and the second abutting portion 131 are integrated into a one-piece structure. In terms of manufacturing process, the second housing 130 including the housing body 132 and the second abutting portion 131 may be formed by, for example, a stamping technique and/or a bending technique.

As stated above, due to the first abutting portion 114 and the first body abutting surface 125s3 abutting against each other and the second abutting portion 131 and the second body abutting surface 125s4 abutting against each other, it may constrain a relative displacement between the first housing 110 and the connector 120 along Y-axis (for example, the third axis), and the first housing 110 and the connector 120 will not easily cause unstable relative shaking due to external force, and the connection stability will not be negatively affected. In addition, the first axis, the second axis and the third axis herein are not parallel to each other, for example, perpendicular to each other.

As illustrated in FIGS. 3A and 3B, the first housing 110 and the second housing 130 may be temporarily fixed together through the fixing element 140. The fixing element 140 is, for example, a threaded element. The fixing element 140 is screwed into a screw hole 110b of the first housing 110 after the fixing element 140 passes through the screw hole 130a of the second housing 130. During an assembly process, the connector 120 may be first passed through the opening 110a from the inside of the first housing 110 to the outside until the first connector abutting portion 121 of the connector 120 abuts against the first housing abutting portion 111 of the first housing 110 and the first elastic portion 122 and the second elastic portion 123 are respectively engaged with the second housing abutting portion 112 and the third housing abutting portion 113 of the first housing 110, and then the second housing 130 is assembled on the first housing 110. Then, a relative position between the second housing 130 and the first housing 110 may be fixed by the fixing element 140. During a disassembly process, the fixing element 140 may be disassembled first, and then the second housing 130 and the first housing 110 may be separated. Compared with a single-piece housing, since the housing of the electronic device 100 according to the embodiment of the present invention is a two-piece housing (i.e., the first housing 110 and the second housing 130), friction problem (which causes damage to the appearance) which is easily caused in the single-piece housing may be improved. For example, after the second housing 130 is separated from the first housing 110, the second abutting portion 131 is also separated from the second body abutting surface 125s4, so that in the process of the connector 120 being separated from the first housing 110 (for example, along +X direction), the second body abutting surface 125s4 will not be scratched by the second abutting portion 131.

Referring to FIG. 4, FIG. 4 illustrates a schematic diagram of a top view of the electronic device 100 in FIG. 1 (the second housing 130 is omitted). The electronic device 100 further includes an electronic component 155 and at least one wire 160. The electronic component 155 is disposed and electrically connected to the circuit board 150. The electronic component 155 is not limited to the marking location in the drawings, and any electronic component disposed on the circuit board 150 may be regarded as the electronic components 155 in this description. The electronic component 155 is, for example, an active component (for example, a chip, etc.) and/or a passive component (for example, a capacitor, an inductor, and/or a resistor, etc.). Although not illustrated, the wire 160 may connect (for example, directly connect or electrically connect) the connector 120 with the circuit board 150. In addition, the number of the wires is not limited herein, and/or the wires 160 may be power wires, signal wires, etc.

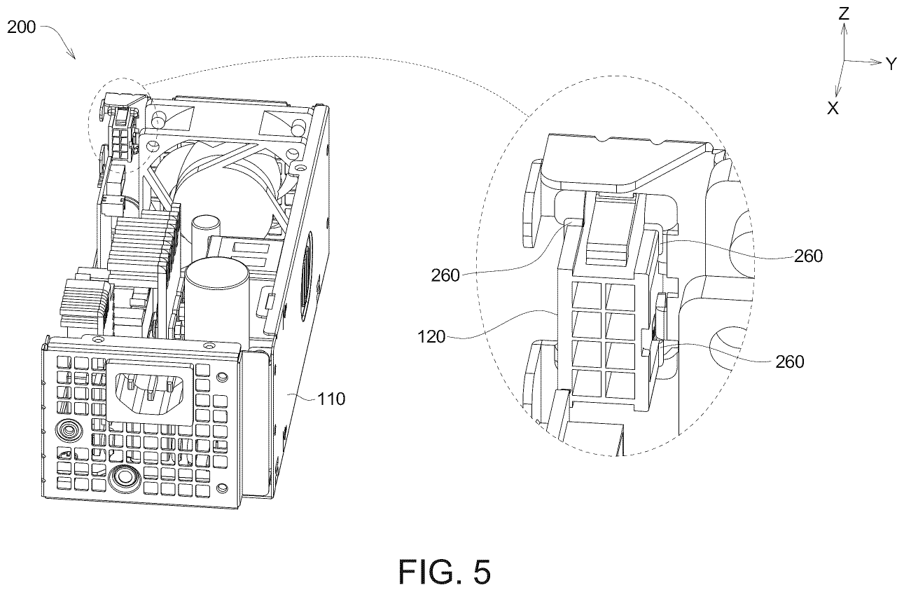

FIG. 5 illustrates a schematic diagram of an electronic device 200 according to another embodiment of the present invention (the second housing 130 is not illustrated). The electronic device 200 includes the technical features the same as or similar to those of the aforementioned electronic device 100, and at least one difference is that the electronic device 200 further includes an adhesive layer 260. The adhesive layer 260 may be formed at a connection between the first housing 110 and the connector 120 to fix the relative positions between the first housing 110 and the connector 120. In the present embodiment, the adhesive layer 260 is not formed at the connection between the second housing 130 and the connector 120, so that the second housing 130 may easily separate from the first housing 110 during disassembly. However, in another embodiment, the adhesive layer 260 may be further formed at the connection between the second housing 130 and the connector 120 for increasing the combination between the housing and the connector 120.

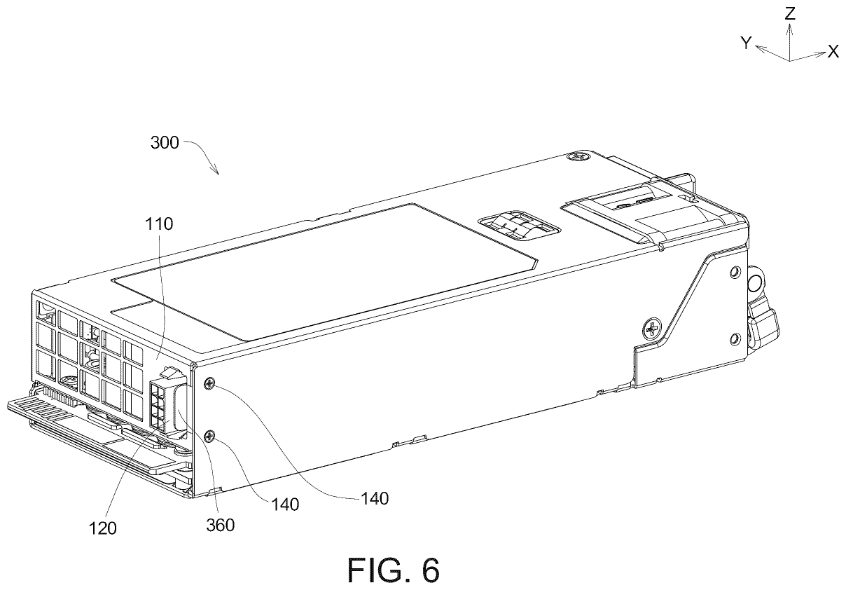

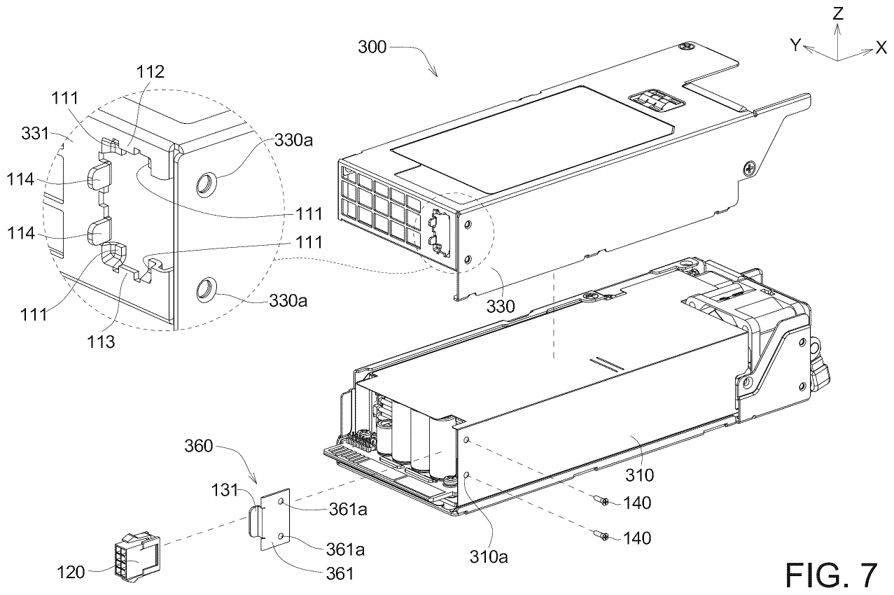

Referring to FIGS. 6 to 7, FIG. 6 illustrates a schematic diagram of an electronic device 300 according to another embodiment of the present invention, and FIG. 7 illustrates a schematic diagram of an exploded view of the electronic device 300 in FIG. 6. The electronic device 300 is, for example, a power supply or other electronic device with a connector.

The electronic device 300 includes the first housing 310, the connector 120, a second housing 330, the circuit board 150 (not illustrated) and an abutting element 360. The electronic device 300 includes the technical features the same as or similar to those of the aforementioned electronic device 100, and at least one difference is that the first abutting structure (the abutting portion and/or the abutting surface, etc.) of the electronic device 100 may be integrated into the second housing 330, and the second abutting portion 131 is detachable relative to the first housing 310.

For example, as illustrated in FIG. 7, the first housing abutting portion 111, the second housing abutting portion 112, the third housing abutting portion 113 and the first abutting portion 114 may be disposed or connected to the second housing 330. In the present embodiment, at least one of the first housing abutting portion 111, the second housing abutting portion 112, the third housing abutting portion 113, the first abutting portion 114 and the housing 331 is integrated into, for example, a one-piece structure. In addition, the abutting element 360 includes a second abutting portion 131 and a fixing element 361. The fixing element 361 is connected to the second abutting portion 131. The first housing 310, the second housing 330 and the abutting element 360 may be temporarily fixed together through the fixing element 140. The fixing element 140 is, for example, a threaded element. The fixing element 140 may be screwed into a screw hole 330a of the second housing 330 after passing through the opening 310a of the first housing 310 and the opening 361a of the fixing element 361. In another embodiment, the abutting element 360 may be integrated into the first housing 310. For example, the abutting element 360 and the first housing 310 are integrated into a one-piece structure.

In summary, the electronic device according to the embodiment of the present invention includes a housing and a connector. In an embodiment, the housing includes a plurality of housing abutting surfaces, and the connector includes a plurality of connector abutting surfaces. A first one of the housing abutting surfaces and a first one of the connector abutting surfaces abut against each other along a first axis, a second one of the housing abutting surfaces and a second one of the connector abutting surfaces abut against each other along a second axis, and a third one of the housing abutting surfaces and a third one of the connector abutting surfaces abut against each other along a third axis. For example, the housing includes a first housing abutting portion (or a first housing abutting surface), and the connector includes a first connector abutting portion (or a first connector abutting surface), wherein the first connector abutting portion and the first housing abutting portion abut against each other along the first axis (for example, X-axis), so that the first housing abutting portion blocks the connector from being separated from the housing along a first direction of the first axis (for example, −X direction). In an embodiment, the housing includes a second housing abutting surface, and the connector includes a second connector abutting surface, wherein the second connector abutting surface and the second housing abutting surface abut against each other along the first axis (for example, X-axis), so that the second housing abutting surface blocks the connector from being separated from the housing along a second direction of the first axis (for example, +X direction). In an embodiment, the housing includes a third housing abutting surface, and the connector includes a third connector abutting surface, wherein the third connector abutting surface and the third housing abutting surface abut against each other along the second axis (for example, Z-axis), so that the third housing abutting surface blocks the connector from being separated from the housing along the first direction of the second axis (for example, +Z direction). In an embodiment, the housing includes a fourth housing abutting surface, and the connector includes a fourth connector abutting surface, wherein the fourth connector abutting surface and the fourth housing abutting surface abut against each other along the second axis (for example, Z-axis), so that the fourth housing abutting surface blocks the connector from being separated from the housing along the second direction of the second axis (for example, −Z direction). In an embodiment, the housing includes a first abutting surface, and the connector includes a first body abutting surface, wherein the first abutting surface and the first body abutting surface abut against each other along the third axis (for example, Y-axis), so that the first abutting surface blocks the connector from being separated from the housing along the first direction of the third axis (for example, +Y direction). In an embodiment, the housing includes a second abutting surface, and the connector includes a second body abutting surface, wherein the second abutting surface and the second body abutting surface abut against each other along the third axis (for example, Y-axis), so that the second abutting surface blocks the connector from being separated from the housing along the second direction of the third axis (for example, −Y direction). Based on the foregoing embodiments, the displacement DoF of the housing and the connector along at least one of the first axis, the second axis and the third axis may be restricted. In other embodiment, the housing may be a multi-piece assembled housing. The multi-piece assembled housing may resolve the friction problem which is easily caused by a single-piece housing.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. An electronic device, comprising:
a first housing comprising a first housing abutting portion and a second housing abutting portion; and
a connector comprising a first connector abutting portion and a second connector abutting surface;
wherein the first housing abutting portion contacts the first connector abutting portion on a first side of the first housing, and the second connector abutting surface contacts the second housing abutting portion on a second side of the first housing.

2. The electronic device according to claim 1, wherein the first housing has an outer surface, the first housing abutting portion extends toward an inside of the first housing relative to the outer surface and has a first housing abutting surface; the connector comprises:
a body having a first lateral surface;
wherein the first connector abutting portion protrudes relative to the first lateral surface and has a first connector abutting surface, and the first housing abutting surface contacts the first connector abutting surface.

3. The electronic device according to claim 1, wherein the first housing has a second housing abutting surface, and the connector comprises:
a body having a first lateral surface; and
a first elastic portion connected to the first lateral surface and provided with the second connector abutting surface, wherein the second connector abutting surface and the second housing abutting surface in contact with each other.

4. The electronic device according to claim 3, wherein the first housing further comprises:
a housing body having an outer surface, wherein the first housing abutting portion protrudes toward an inside of the first housing relative to the outer surface;
wherein the second housing abutting portion is connected to the housing body and provided with the second housing abutting surface, and the second housing abutting portion extends toward the first lateral surface.

5. The electronic device according to claim 3, wherein the first housing has a third housing abutting surface connected to the second housing abutting surface, and the first elastic portion further has a third connector abutting surface in contact with the third housing abutting surface.

6. The electronic device according to claim 5, wherein the second connector abutting surface intersects the third connector abutting surface.

7. The electronic device according to claim 5, wherein the first housing has a fourth housing abutting surface facing a direction opposite to the third housing abutting surface; the connector further comprises:
a body having a second lateral surface opposite to the first lateral surface; and
a second elastic portion connected to the second lateral surface and provided with a fourth connector abutting surface in contact with the fourth housing abutting surface.

8. The electronic device according to claim 3, wherein a third housing abutting surface of the first housing is in contact with a third connector abutting surface of the first elastic portion, and the second connector abutting surface intersects the third connector abutting surface.

9. The electronic device according to claim 1, wherein the first housing further comprises:
a first abutting portion extending toward an outside of the first housing;
wherein the connector comprises:
a body having a first body abutting surface adjacent to the first lateral surface and in contact with the first abutting portion.

10. The electronic device according to claim 9, further comprising:
a second housing comprising a second abutting portion extending toward an outside of the second housing;
wherein the body has a second body abutting surface opposite to the first body abutting surface and in contact with the second abutting.

11. The electronic device according to claim 1, further comprising:
an adhesive layer connecting the first housing abutting portion and the first connector abutting portion.

12. The electronic device according to claim 1, further comprising:
a circuit board disposed inside the first housing;
an electronic component disposed on and electrically connected to the circuit board; and
a wire connecting the connector with the circuit board.

13. The electronic device according to claim 1, wherein a distance between the first connector abutting portion and the second connector abutting surface is greater than a thickness of the first housing.

14. An electronic device, comprising:
a first housing comprising a first abutting portion extending outward from the first housing at a position corresponding to an opening; and
a connector disposed in the opening of the first housing, wherein the connector comprises a first body abutting surface in contact with the first abutting portion.

15. The electronic device according to claim 14, further comprising:
a second housing comprising a second abutting portion extending outward from the second housing at a position corresponding to the opening;
wherein the body has a second body abutting surface opposite to the first body abutting surface and in contact with the second abutting portion.

16. The electronic device according to claim 14, wherein the connector comprises a portion protruding outward from the first housing corresponding to an extension direction of the first abutting portion.

17. An electronic device, comprising:
a housing comprising a first housing abutting surface and a second housing abutting surface; and
a connector comprising a first connector abutting surface and a second connector abutting surface;
wherein the first housing abutting surface is in contact with the first connector abutting surface along an axis, the second housing abutting surface is in contact with the second connector abutting surface along the axis.

18. The electronic device according to claim 17, wherein a first abutting surface of the housing and a first body abutting surface of the connector are in contact along another axis which is substantially perpendicular to the axis.

19. The electronic device according to claim 17, wherein the connector comprises:
a body; and
a first elastic portion connected to the body, wherein the first elastic portion has the first connector abutting surface, the second connector abutting surface and a first free end, and the first free end positioned outside the housing and the body are separated by a gap.

20. The electronic device according to claim 19, wherein the connector further comprises a second elastic portion connected to the body and located opposite to the first elastic portion, and the second elastic portion has a second free end spaced from the body.
